(19) United States
(12) Patent Application Publication
(10) Pub. No.: US 2024/0379169 A1
(43) Pub. Date: Nov. 14, 2024

(54) MEMORY AND OPERATION METHOD THEREOF, MEMORY SYSTEM AND ELECTRONIC DEVICE

(71) Applicant: Yangtze Memory Technologies Co., Ltd., Wuhan (CN)

(72) Inventors: Teng Chen, Wuhan (CN); Ke Liang, Wuhan (CN); Weijun Wan, Wuhan (CN); Weiwei He, Wuhan (CN)

(21) Appl. No.: 18/485,084

(22) Filed: Oct. 11, 2023

(30) Foreign Application Priority Data
May 10, 2023 (CN) 202310526885.8

(51) Int. Cl. G11C 16/24; G11C 16/04

(52) U.S. Cl. CPC G11C 16/24; G11C 16/0483; G11C 16/08

(57) ABSTRACT

Examples of the present disclosure disclose a memory and an operation method thereof, a memory system and an electronic device. The memory includes a memory cell array and a page buffer, wherein the page buffer is disposed correspondingly to a bit line of the memory cell array and includes: latches which are coupled to the bit line through a sense node of the page buffer; and at least one common data transmission circuit, wherein a first port of the common data transmission circuit is coupled with the sense node and a second port of the common data transmission circuit is coupled with at least two of the latches, wherein the at least two of the latches are configured for data sensing through the common data transmission circuit respectively.

### CROSS-REFERENCE TO RELATED APPLICATIONS

This application claims priority to Chinese Patent Application No. 202310526885.8, filed on May 10, 2023, which is hereby incorporated by reference in its entirety.

### TECHNICAL FIELD

Examples of the present disclosure relate to a semiconductor technology, and particularly to, but not limited to, a memory and an operation method thereof, a memory system and an electronic device.

### BACKGROUND

Semiconductor memories may be roughly divided into two categories, depending on whether they retain stored data in the case of power failure. Such two categories of semiconductor memories are: volatile memories and non-volatile memories. The volatile memories lose the stored data in the case of the power failure, and the non-volatile memories retain the stored data in the case of the power failure. Memory cells in the non-volatile memories are connected to bit lines and word lines respectively, and thus have good random access time characteristics.

With the increase of an integration level of the memory, the area occupied by a page buffer in a peripheral circuit of the memory is limited and there is a need that its area tends to decrease, such that the number of elements constituting the page buffer also needs to be reduced.

### SUMMARY

In view of this, examples of the present disclosure provide a memory and an operation method thereof, a memory system and an electronic device.

In a first aspect, examples of the present disclosure provide a memory. The memory comprises a memory cell array and a page buffer, wherein the page buffer is disposed correspondingly to a bit line of the memory cell array, and the page buffer comprises: a plurality of latches which are coupled to the bit line through a sense node of the page buffer; and at least one common data transmission circuit, wherein a first port of the common data transmission circuit is coupled with the sense node, and a second port of the common data transmission circuit is coupled with at least two of the latches, wherein the at least two of the latches perform data sensing through the common data transmission circuit respectively.

In a second aspect, examples of the present disclosure further provide an operation method of a memory. The memory comprises a memory cell array and a page buffer, wherein the page buffer is disposed correspondingly to a bit line of the memory cell array, wherein the page buffer comprises a plurality of latches and at least one common data transmission circuit, wherein a first port of the common data transmission circuit is coupled with a sense node, and a second port of the common data transmission circuit is coupled with at least two of the latches. The operation method comprises: performing a precharge operation on the sense node such that the sense node have a first voltage; in response to the first voltage, performing a first data setting operation on a first latch of at least two of the latches; sensing data in a second latch of the at least two of the latches through the common data transmission circuit and generating a sensing result such that the sense node have a second voltage, wherein the second voltage is less than or equal to the first voltage; and in response to the sensing result, performing a second data setting operation on the first latch.

In a third aspect, examples of the present disclosure further provide a memory system which comprises: one or more memories of any one of the above examples; and a memory controller coupled to the one or more memories and configured to control the one or more memories.

In a fourth aspect, examples of the present disclosure further provide an electronic device which comprises the memory system as described in the above examples.

In the examples of the present disclosure, at least two of the latches in the page buffer are configured to share one common data transmission circuit, and each latch connected to the same common data transmission circuit can perform data sensing through the common data transmission circuit, such that the number of data transmission circuits in the page buffer is saved, and the area of the page buffer is saved, which is favorable to the reduction of the area of a peripheral circuit in the memory.

Moreover, in the examples of the present disclosure, data sensing of the plurality of latches may be achieved by at least using one common data transmission circuit, and the reduction of independent data transmission circuits can not only reduce the area of the page buffer, but also reduce the number of corresponding control signal circuits and relevant routing in the memory.

### BRIEF DESCRIPTION OF THE DRAWINGS

In the drawings, like reference numerals may describe like components in different views. Like reference numerals having different letter suffixes may represent different examples of like components. The drawings illustrate generally, by way of example, but not by way of limitation, various examples as discussed herein.

FIG. 1A is a schematic structure diagram of an example system provided by an example of the present disclosure;

FIG. 1B is a schematic structure diagram of a memory card provided by an example of the present disclosure;

FIG. 1C is a schematic structure diagram of a Solid State Disk (SSD) provided by an example of the present disclosure;

FIGS. 1D and 1E are schematic structure diagrams of a memory comprising a memory cell array and a peripheral circuit provided by an example of the present disclosure;

FIG. 1F is a schematic structure diagram of a memory comprising a page buffer provided by an example of the present disclosure;

FIG. 2 is a schematic diagram of a page buffer provided by an example;

FIG. 3A is a schematic diagram I of a page buffer provided by examples of the present disclosure;

FIG. 3B is a schematic diagram II of a page buffer provided by examples of the present disclosure;

FIG. 4 is a schematic diagram III of a page buffer provided by examples of the present disclosure;

FIG. 5 is a schematic diagram of a control logic circuit provided by examples of the present disclosure;

FIG. 6 is a schematic diagram of a latch provided by examples of the present disclosure;

FIG. 7 is a schematic diagram IV of a page buffer provided by examples of the present disclosure;

FIG. 8 is a flow diagram of an operation method of a memory provided by examples of the present disclosure; and

FIG. 9 is a timing diagram of an operation method of a memory provided by examples of the present disclosure.

### DETAILED DESCRIPTION

In order to facilitate the understanding of the present disclosure, the present disclosure will be described below more comprehensively with reference to the relevant drawings. Examples of the present disclosure are given in the drawings. However, the present disclosure may be implemented in many different forms, and is not limited to the examples described herein. Instead, the purpose of providing these examples is to make the disclosure of the present disclosure more thorough and comprehensive.

Unless otherwise defined, all technical and scientific terms used herein have the same meanings as those generally understood by those skilled in the art. The terms used in the specification of the present disclosure are only for the purpose of describing specific examples, and are not intended to limit the present disclosure. The term “and/or” used herein include any and all combinations of one or more listed associated items.

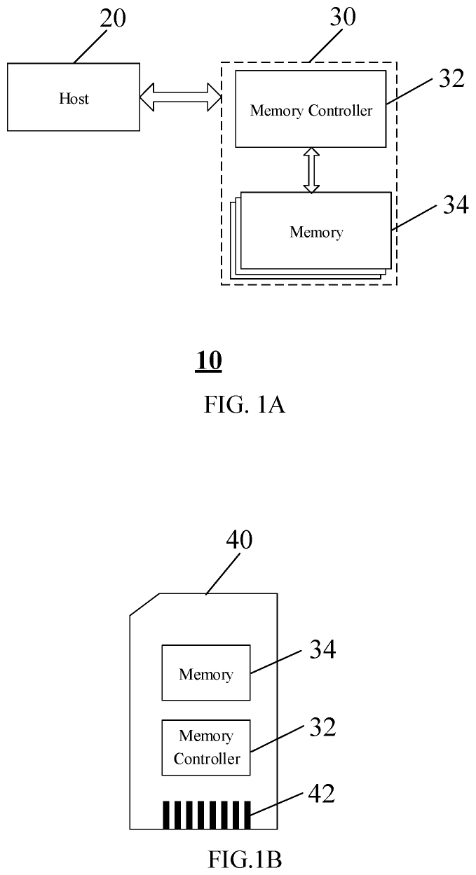

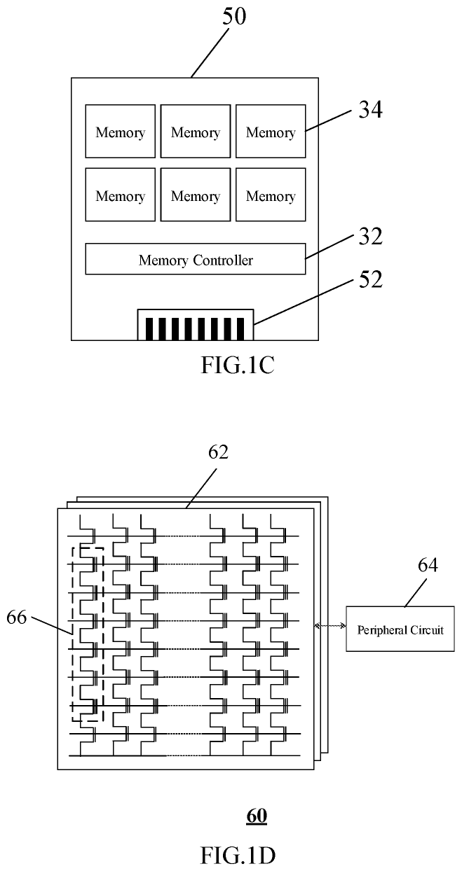

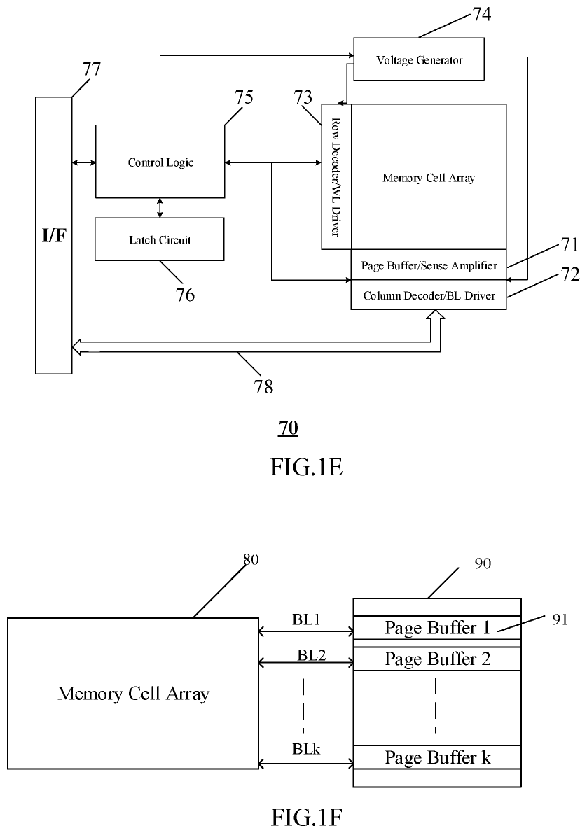

As shown in FIG. 1A, examples of the present disclosure illustrate an example system 10. The example system 10 may comprise a host 20 and a memory system 30. The example system 10 may include, but is not limited to, a mobile phone, a desktop computer, a laptop computer, a tablet computer, a vehicle computer, a gaming console, a printer, a positioning device, a wearable electronic device, a smart sensor, a Virtual Reality (VR) device, an Augmented Reality (AR) device, or any other suitable electronic device having memories 34 therein, and the host 20 may be a processor (e.g., a Central Processing Unit (CPU)) or a System on Chip (SoC) (e.g., an Application Processor (AP)) of an electronic device.

In an example of the present disclosure, the host 20 may be configured to send or receive data to or from the memory system 30. Here, the memory system 30 may comprise a memory controller 32 and one or more memories 34. The memories 34 may include, but are not limited to, a NAND Flash Memory, a Vertical NAND Flash Memory, a NOR Flash Memory, a Dynamic Random Access Memory (DRAM), a Ferroelectric Random Access Memory (FRAM), a Magnetoresistive Random Access Memory (MRAM), a Phase Change Random Access Memory (PCRAM), a Resistive Random Access Memory (RRAM), and a Nano Random Access Memory (NRAM), etc.

In an example of the present disclosure, the memory controller 32 may be coupled to the memories 34 and the host 20, and is configured to control the memories 34. In an example, the memory controller 32 may be designed for operating in a low duty-cycle environment such as Secure Digital (SD) cards, Compact Flash (CF) cards, Universal Serial Bus (USB) flash drives, or other media for use in electronic devices, such as personal computers, digital cameras, mobile phones, etc. In some examples, the memory controller 32 may be also designed for operating in a high duty-cycle environment such as SSDs or embedded Multi-Media Cards (eMMCs), and SSDs or eMMCs may be used as data memories for mobile devices, such as smartphones, tablet computers, laptop computers, etc., and enterprise memory arrays.

Further, the memory controller 32 can manage data in the memories 34 and communicate with the host. The memory controller 32 may be configured to control read, erase and program operations etc. of the memories 34, may be further configured to manage various functions with respect to data stored or to be stored in the memories 34, including, but not limited to, bad-block management, garbage collection, logical-to-physical address conversion, wear leveling, etc., and may be further configured to process Error Checking and Correction (ECC) with respect to the data read from or written to the memories 34. Furthermore, the memory controller 32 may further perform any other suitable functions as well, for example, formatting the memories 34 or communicating with an external device (e.g., the host 20 in FIG. 1A) according to a particular communication protocol. In an example, the memory controller 32 may communicate with an external host through at least one of various interface protocols, such as a USB protocol, a MMC protocol, a Peripheral Component Interconnect (PCI) protocol, a Peripheral Component Interconnect Express (PCI-E) protocol, an Advanced Technology Attachment (ATA) protocol, a serial ATA protocol, a parallel ATA protocol, a Small Computer System Interface (SCSI) protocol, an Enhanced Small Drive Interface (ESDI) protocol, an Integrated Development Equipment (IDE) protocol, and a Firewire protocol, etc.

In an example of the present disclosure, the memory controller 32 and the one or more memories 34 may be integrated into various types of storage devices, for example, be included in the same package, such as a Universal Flash Storage (UFS) package or an eMMC package. That is to say, the memory system 30 may be implemented and packaged into different types of end electronic products. As shown in FIG. 1B, the memory controller 32 and a single memory 34 may be integrated together to form a memory card 40. The memory card 40 may include a Personal Computer Memory Card International Association (PC) card, a CF card, a Smart Media (SM) card, a memory stick, a Multi-Media Card (MMC, Reduced-Size MMC (RS-MMC), and MMCmicro), an SD card (SD, miniSD, microSD, Secure Digital High Capacity (SDHC)), and a UFS, etc. The memory card 40 may further comprise a memory card connector 42 coupling the memory card 40 to a host (e.g., the host 20 in FIG. 1A). In another example as shown in FIG. 1C, the memory controller 32 and a plurality of memories 34 may be integrated together to form an SSD 50. The SSD 50 may further comprise an SSD connector 52 coupling the SSD 50 to a host (e.g., the host 20 in FIG. 1A). In some examples, the storage capacity and/or the operation speed of the SSD 50 are greater than the storage capacity and/or the operation speed of the memory card 40.

It is to be noted that the memory involved in an example of the present disclosure may be a semiconductor memory, which is a solid-state electronic device made by a semiconductor integrated circuit process for storing data information. In an example, FIG. 1D is a schematic diagram of an optional memory 60 in the examples of the present disclosure. The memory 60 may be the memory 34 in FIGS. 1A through 1C. As shown in FIG. 1D, the memory 60 may comprise a memory cell array 62 and a peripheral circuit 64 coupled to the memory cell array 62, etc. Here, the memory cell array may be a NAND flash memory cell array in which memory cells are disposed in a form of an array of NAND memory strings 66 each extending vertically above a substrate. In some examples, each NAND memory string 66 may comprise a plurality of memory cells that are coupled in series and stacked vertically. Each memory cell may hold a continuous analog value, such as a voltage or charge, which depends on the number of electrons trapped within a region of the memory cell. In addition, each memory cell in the above-mentioned memory cell array 62 may be either a floating gate type memory cell that includes a floating gate transistor, or a charge trapping type memory cell that includes a charge trapping transistor.

In an example of the present disclosure, the memory cell above may be a Single Level Cell (SLC) that has two possible memory states, and thus can store one bit of data. For example, the first memory state “0” may correspond to a first threshold voltage range, and the second memory state “1” may correspond to a second threshold voltage range. In some other examples, each memory cell may be a Multi Level Cell (MLC) that is capable of storing more than a single bit of data in more than four memory states. For example, the MLC may store two bits per cell, three bits per cell (also known as a Triple Level Cell (TLC)), or four bits per cell (also known as a Quad Level Cell (QLC)). Each MLC may be programmed to a range of possible nominal storage values. In an example, if each MLC stores two bits of data, the MLC may be programmed to write one of three possible nominal storage values to the memory cell, such that the memory cell is programmed from an erased state to one of three possible programming levels. A fourth nominal storage value may be used for the erased state.

In the examples of the present disclosure, the above-mentioned peripheral circuit may be coupled to the memory cell array through a Bit Line (BL), a Word Line (WL), a Source Line, a Source Select Gate (SSG) and a Drain Select Gate (DSG). Here, the peripheral circuit may include any suitable analog, digital, and hybrid signal circuits for facilitating relevant operations of the memory cell array by applying and sensing voltage signals and/or current signals to and from each target memory cell via the bit line, the word line, the source line, the SSG, or the DSG, etc. Furthermore, the peripheral circuit may further include various types of peripheral circuits formed using a Metal-Oxide-Semiconductor (MOS) technology. In an example, as shown in FIG. 1E, a peripheral circuit 70 may comprise a Page Buffer (PB)/sense amplifier 71, a column decoder/bit line driver 72, a row decoder/word line driver 73, a voltage generator 74, a control logic 75, a latch circuit 76, an interface 77 and a data bus 78. It should be understood that the above-mentioned peripheral circuit 70 may be the same as the peripheral circuit 64 in FIG. 1D, and in some other examples, the peripheral circuit 70 may further comprise additional peripheral circuits not shown in FIG. 1E.

As shown in FIG. 1F, a page buffer group 90 is illustrated in an example of the present disclosure. The page buffer group 90 may be coupled with a memory cell array 80 via a plurality of bit lines BL1 through BLk. The page buffer group 90 may comprise a Page Buffer 1 (PB1) to a Page Buffer k (PBk), and each page buffer is coupled with the memory cell array via a bit line. For example, the page buffers PB1 through PBk may be coupled with the memory cell array via the respective bit lines BL1 through BLk, respectively.

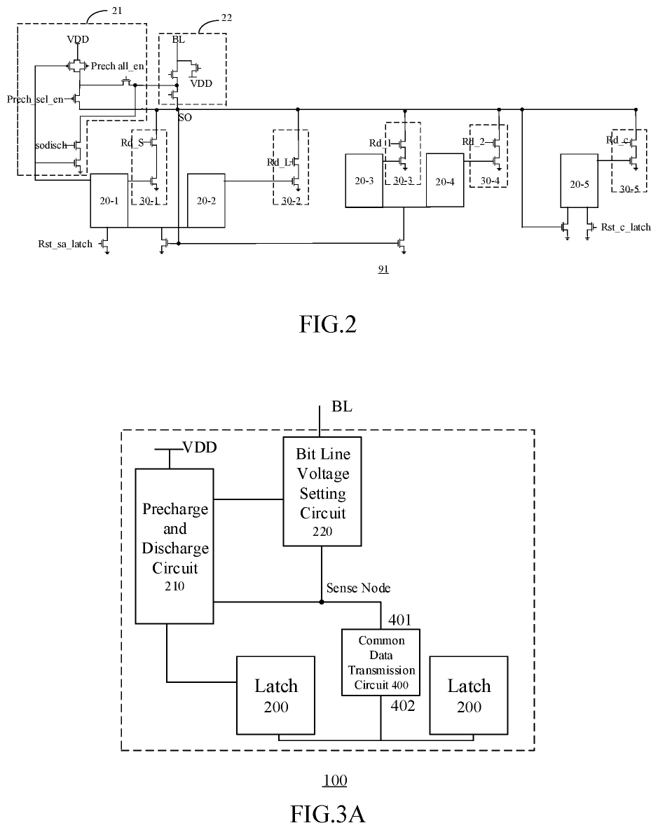

In some examples, as shown in FIG. 2, a page buffer 91 comprises a precharge and discharge circuit 21, a bit line voltage setting circuit 22 and a plurality of latches, wherein the latches may comprise a Sense Latch (S Latch) 20-1, a Low Voltage Latch (LVT Latch) 20-2, Data Latches (D Latch) such as a D1 latch 20-3 and a D2 latch 20-4, and a Cache Latch (C Latch) 20-5.

The precharge and discharge circuit 21 is configured to regulate a voltage of a bit line BL in the process of performing logic (e.g., program, read or write) operations. For example, whether to charge the bit line may be determined according to a program verify result latched in the sense latch 20-1. For example, when the program verify result indicates that a memory cell reaches a target threshold voltage, the bit line coupled to the memory cell may be charged to a program inhibited bit line voltage (e.g., VDD) through the precharge and discharge circuit 21, so as to inhibit program; and when the program verify result indicates that the memory cell does not reach the target threshold voltage, the bit line coupled to the memory cell may be regulated to a normal program bit line voltage (e.g., VSS) or a bit line force voltage (greater than VSS and less than VDD) through the precharge and discharge circuit 21, so as to continue the program.

The precharge and discharge circuit 21 is further configured to regulate a voltage at a sense node SO in the process of performing logic operations.

In some examples, the precharge and discharge circuit 21 may directly set the voltage at the sense node SO without using data latched in the sense latch 20-1.

For example, when a Prech_sel_en signal and a Prech_all_en signal are simultaneously enabled, a power supply voltage (VDD) may be applied to the sense node through the precharge and discharge circuit 21.

The bit line voltage setting circuit 22 is configured to provide different bit line force voltages to the bit line, such that a finer program operation may be performed on the memory cell when the program operation is performed.

For the example as shown in FIG. 2, each latch may be connected with a corresponding independent data transmission circuit, for example, the sense latch 20-1 is connected with a first independent data transmission circuit 30-1, the low voltage latch 20-2 is connected with a second independent data transmission circuit 30-2, the D1 latch 20-3 is connected with a third independent data transmission circuit 30-3, the D2 latch 20-4 is connected with a fourth independent data transmission circuit 30-4, and the cache latch 20-5 is connected with a fifth independent data transmission circuit 30-5.

Each independent data transmission circuit may be configured to perform a data sensing operation on the corresponding latch. The illustration is made below by taking the sense latch 20-1 performing data sensing using the first independent data transmission circuit 30-1 as an example.

The sense node SO is charged by the precharge and discharge circuit 21, such that the sense node SO has a high voltage (e.g., a power supply voltage).

The first independent data transmission circuit 30-1 receives a first independent data transmission signal Rd_s. If data stored in the sense latch 20-1 is “1”, the first independent data transmission circuit 30-1 is turned on, and the high voltage on the sense node SO may be discharged to a low voltage through the first independent data transmission circuit 30-1. If the data stored in the sense latch 20-1 is “0”, the first independent data transmission circuit 30-1 is turned off, the high voltage on the sense node SO may not be discharged through the first independent data transmission circuit 30-1, and the voltage on the sense node SO is still the high voltage.

Therefore, data information stored in the sense latch may be obtained by sensing the voltage at the sense node SO at this time. Similarly, by using the independent data transmission circuit corresponding to each latch, data information stored in the latch may be sensed.

For the page buffer 91 as shown in FIG. 2, since each latch corresponds to one independent data transmission circuit, the area of the page buffer 91 is too large, and in the context of the increasing miniaturization of memories, how to reduce the area of the page buffer 91 has become an urgent problem to be solved.

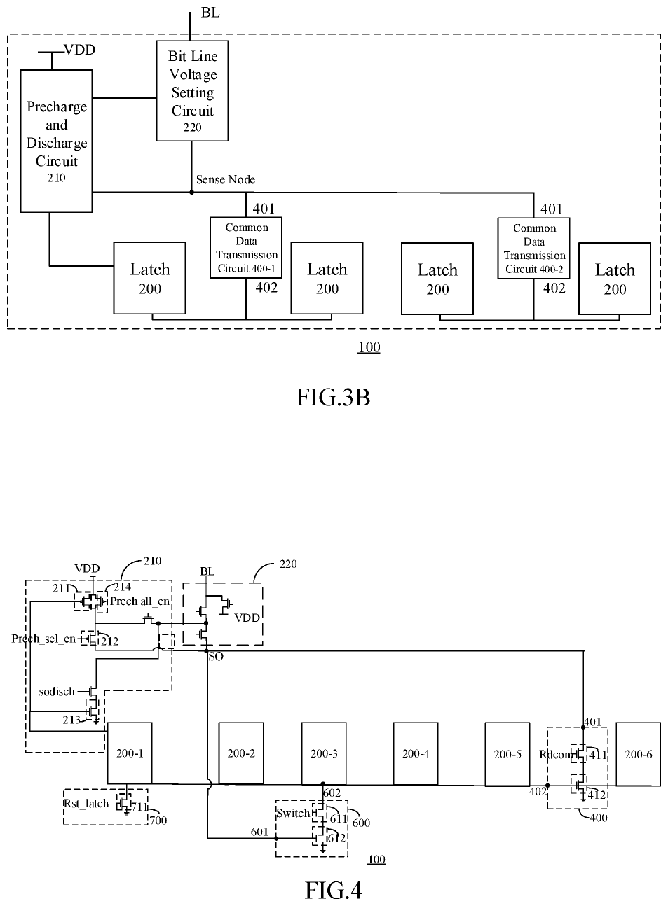

In order to solve the above problem, examples of the present disclosure provide a memory. The memory comprises a memory cell array and a page buffer, and the page buffer is disposed correspondingly to a bit line of the memory cell array. As shown in FIG. 3A, the page buffer 100 comprises: a plurality of latches 200 which are coupled to the bit line BL through a sense node SO of the page buffer 100; and at least one common data transmission circuit 400, wherein a first port 401 of the common data transmission circuit 400 is coupled with the sense node SO, a second port 402 of the common data transmission circuit 400 is coupled with at least two of the latches 200, and the at least two of the latches perform data sensing through the common data transmission circuit 400 respectively.

In the examples of the present disclosure, the page buffer 100 comprises at least two latches (e.g., 2, 3, 4 . . . ), wherein at least two of the latches 200 share one common data transmission circuit 400, and each latch 200 connected to the same common data transmission circuit 400 can perform the data sensing through the common data transmission circuit 400, such that the number of data transmission circuits in the page buffer is saved, and the area of the page buffer is saved, which is favorable to the reduction of the area of a peripheral circuit in the memory.

Moreover, in the examples of the present disclosure, the data sensing of the plurality of latches 200 may be achieved by at least using one common data transmission circuit 400, and the reduction of independent data transmission circuits 300 can not only reduce the area of the page buffer, but also reduce the number of corresponding control signal circuits and relevant routing in the memory.

As shown in FIG. 3B, the examples of the present disclosure may further comprise at least two common data transmission circuits 400 (e.g., 400-1 and 400-2), and each common data transmission circuit 400 may be connected with at least two of the latches 200. Compared with that the four latches are connected with different independent data transmission circuits in FIG. 2, the at least two common data circuits (400-1 and 400-2) are used in FIG. 3, which can still save the number of the data transmission circuits in the page buffer to some extent, such that the area of the page buffer is saved, which is favorable to the reduction of the area of the peripheral circuit in the memory.

FIG. 3A describes the page buffer 100 of the page buffers PB1 through PBk as shown in FIG. 1F as an example. It should be noted that the rest of the page buffers may have the same configuration as the page buffer 100.

In some examples, as shown in FIG. 3A, the page buffer 100 further comprises: a precharge and discharge circuit 210 which is coupled to a power terminal VDD and the sense node SO respectively. The precharge and discharge circuit 210 may be configured to regulate a bit line voltage during program. For example, the voltage is applied to the bit line to achieve precharge of the bit line; or the bit line voltage is pulled down to a ground voltage to achieve discharge of the bit line.

In some examples, in the process of performing the program on the memory cell, a program inhibited bit line voltage (e.g., VDD) or a normal program bit line voltage (e.g., VSS) may be applied to the bit line connected with the memory cell by the precharge and discharge circuit 210. In an example, a high level is applied to the bit line through a charge function of the precharge and discharge circuit 210 to achieve an effect of inhibiting the program, or the bit line is discharged through a discharge function of the precharge and discharge circuit 210, such that the voltage of the bit line is pulled down to the ground voltage to achieve an effect of allowing the program.

As shown in FIG. 3A, the page buffer 100 further comprises: a bit line voltage setting circuit 220 which is coupled to the precharge and discharge circuit 210, the sense node SO and the bit line BL respectively, wherein the precharge and discharge circuit 210 is configured to provide a first voltage from the power terminal (e.g., a power supply voltage) to at least one of the bit line voltage setting circuit 220 or the sense node SO, and the bit line voltage setting circuit 220 is configured to provide a bit line force voltage to the bit line based on the first voltage provided by the precharge and discharge circuit 210, where the normal program bit line voltage <the bit line force voltage <the program inhibited bit line voltage. The bit line voltage setting circuit 220 may comprise a plurality of bit line voltage setting components, and different bit line force voltages, for example, a first bit line force voltage and a second bit line force voltage, may be generated based on the different bit line voltage setting components, with the normal program bit line voltage <the first bit line force voltage <the second bit line force voltage <the program inhibited bit line voltage.

Each of the above-mentioned bit line voltage setting components may be an NMOS transistor, or a PMOS transistor, or a combination of a plurality of NMOS transistors and/or a plurality of PMOS transistors. The bit line voltage setting components may be also other components for clamping or regulating voltages, such as Zener diodes, transient voltage suppressors, piezoresistors, etc.

By using the bit line voltage setting circuit 220, fine program of the memory cell can be achieved by applying different bit line force voltages to the bit line based on the precharge and discharge circuit 210, such that a target threshold voltage distribution is narrower, a read window between the memory cells in different program states is increased, and accurate reading of the data is ensured.

In some examples, data transmission is performed between at least two of the latches 200 through the common data transmission circuit 400.

The common data transmission circuit 400 may not only be used for data sensing, but also for data transmission between the different latches 200.

As shown in FIG. 3A, a value of one of the latches 200 may be sensed using the common data transmission circuit 400, and a sensing result may be obtained. The sensing result may be embodied in a voltage variation or a final voltage value of the sense node SO. Then, data setting may be performed on another one of the latches 200 according to the sensing result, thereby achieving a function of data transmission between at least two of the latches 200. For example, when the sensing result represents that the data latched in one of the latches 200 is “1”, another one of the latches 200 may be also set as “1” using the obtained sensing result, that is, the data latched in one of the latches 200 is transmitted to another one of the latches 200.

In some examples, as shown in FIG. 4, the page buffer 100 further comprises: a first data setting circuit 600, with a first port 601 of the first data setting circuit 600 being coupled with the sense node SO and a second port 602 of the first data setting circuit 600 being coupled with the at least two of the latches 200 (e.g., 200-1 through 200-6), wherein the first data setting circuit 600 is configured to set the data latched in the latches 200; the second port 402 of the common data transmission circuit 400 is coupled to a coupling node between the second port 602 of the first data setting circuit 600 and the at least two of the latches 200.

In some examples, the first data setting circuit 600 comprises: a first transistor 611 and a second transistor 612 that are connected in series; a first end of the first transistor 611 is coupled to the second port 602 of the first data setting circuit 600, a second end of the first transistor 611 is coupled to a first end of the second transistor, and a second end of the second transistor 612 is coupled to a ground terminal, wherein a control end of the second transistor 612 is coupled to the sense node SO, and a control end of the first transistor 611 is configured to receive a first data setting signal Switch.

The first transistor 611 and the second transistor 612 include, but are not limited to, P-type transistors or N-type transistors. In the examples of the present disclosure, the illustration is made by taking the first transistor 611 and the second transistor 612 being the N-type transistors as an example.

When the first data setting signal Switch is enabled and a voltage at the sense node SO is at a high level, a value in any latch 200 may be set using the first data setting circuit 600. The first data setting circuit 600 may simultaneously set the values in one or more of the latches 200, which may be specifically set according to actual requirements.

It may be understood that, in some examples, the first transistor 611 and the second transistor 612 may also be P-type transistors. When the first data setting signal Switch is enabled and the voltage at the sense node SO is at a low level, the value in any latch 200 may be set using the first data setting circuit 600.

In some examples, the first transistor 611 may also be replaced with a thyristor and a switching element.

For ease of understanding, the explanation is made below by taking using the first data setting circuit 600 to set the data in a sense latch 200-1 as an example. It is to be noted that other latches in the page buffer may perform similar methods for data setting operations.

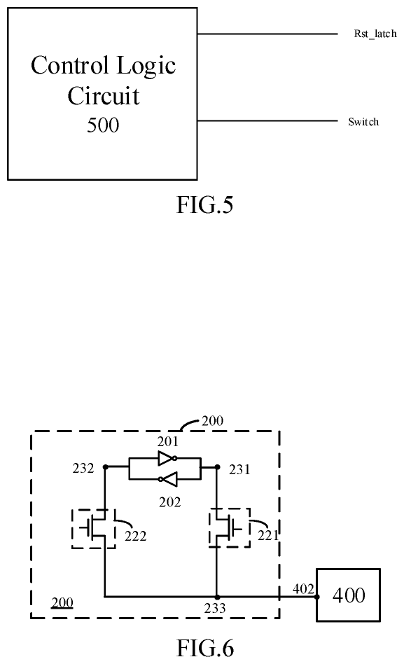

For example, the voltage at the sense node SO is precharged to a high voltage using the precharge and discharge circuit 210. Then, the first data setting signal Switch is enabled, such that the first data setting circuit 600 is turned on. Meanwhile, a fifth transistor 222 in FIG. 6 is turned on, such that a ground voltage from the ground terminal may be provided to a second node 232 of the sense latch 200-1, that is, the sense latch 200-1 is set as the data “1”.

For another example, the voltage at the sense node SO is precharged to the high voltage using the precharge and discharge circuit 210. Then, the first data setting signal Switch is enabled, such that the first data setting circuit 600 is turned on. Meanwhile, a fourth transistor 221 in FIG. 6 is turned on, such that the ground voltage from the ground terminal may be transmitted to a first node 231 of the sense latch 200-1, that is, the sense latch 200-1 is set as the data “0”.

It is to be noted that the data “1” may represent a high level or a low level, and the data “0” may represent a low level or a high level. In the examples of the present disclosure, the illustration is made by taking the data “1” representing the high level and the data “0” representing the low level as an example.

In some examples, as shown in FIG. 4, the page buffer 100 further comprises: a second data setting circuit 700 comprising: a third transistor 711, wherein a first end of the third transistor 711 is coupled to the second port 402 of the common data transmission circuit 400, a second end of the third transistor 711 is coupled to the ground terminal, and a control end of the third transistor 711 is configured to receive a second data setting signal Rst_latch.

The third transistor 711 includes, but is not limited to, a P-type transistor or an N-type transistor. In the examples of the present disclosure, the illustration is made by taking the third transistor 711 being the N-type transistor as an example.

Different from the first data setting circuit 600, the second data setting circuit 700 is a forced setting circuit, that is, when the second data setting signal Rst_latch is enabled, regardless of the voltage magnitude of the sense node at this time, data setting may be performed on the designated latch 200.

In the examples of the present disclosure, prior to enabling the page buffer, data set or reset operations may be performed on one or more of the latches 200 in the page buffer 100 using the second data setting circuit 700.

It is to be noted that the binary data “0” or “1” may represent a set operation or a reset operation. In some examples, the set operation corresponds to setting the data in the latch as “1”, and the reset operation corresponds to setting the data in the latch as “0”. In other examples, the set operation corresponds to setting the data in the latch as “0”, and the reset operation corresponds to setting the data in the latch as “1”.

In some examples, as shown in FIG. 5, the memory further comprises: a control logic circuit 500 which is coupled with the first data setting circuit and the second data setting circuit respectively, wherein the control logic circuit 500 is configured to generate at least one of the first data setting signal Switch and the second data setting signal Rst_latch.

The control logic circuit 500 may be configured to generate various control signals required by the page buffer 100, including, but not limited to, the first data setting signal Switch and the second data setting signal Rst_latch.

The function of the control logic circuit 500 is similar to the function of the control logic 75 in FIG. 1E, and the control logic is configured to generate various control signals, so as to achieve various logic operations (such as read operation, write operation, erase operation, and sense operation, etc.) for the memory cells.

In some examples, as shown in FIG. 6, the latch 200 comprises: a first phase inverter 201, a second phase inverter 202, a fourth transistor 221 and a fifth transistor 222; an output end of the first phase inverter 201 is coupled with an input end of the second phase inverter 202, and an input end of the first phase inverter 201 is coupled with an output end of the second phase inverter 202; a first end of the fourth transistor 221 is coupled to a first node 231 between the output end of the first phase inverter 201 and the input end of the second phase inverter 202, a first end of the fifth transistor 222 is coupled to a second node 232 between the input end of the first phase inverter 201 and the output end of the second phase inverter 202, and a second end of the fourth transistor 221 and a second end of the fifth transistor 222 are coupled to a third node 233, wherein the third nodes 233 of at least two of the latches 200 are coupled to the second port 402 of the common data transmission circuit 400.

In some examples, the fourth transistor 221 is a set transistor, and the fifth transistor 222 is a reset transistor; alternatively, the fourth transistor 221 is a reset transistor, and the fifth transistor 222 is a set transistor. The fourth transistor 221 and the fifth transistor 222 include, but are not limited to, P-type transistors or N-type transistors. In the examples of the present disclosure, the illustration is made by taking the fourth transistor 221 and the fifth transistor 222 both being the N-type transistors as an example.

In conjunction with FIGS. 4 through 6, when at least one of the first data setting circuit 600 or the second data setting circuit 700 is in an ON state, the ground voltage of the ground terminal may be transmitted to the second port 402 of the common data transmission circuit 400 (i.e., the third node 233 of the latch 200 in FIG. 6) using at least one of the first data setting circuit 600 or the second data setting circuit 700, that is, the third node 233 of the latch 200 and the second port 402 of the common data transmission circuit 400 are equivalent potential nodes.

When the fourth transistor 221 in the latch 200 is turned on, the ground voltage may be transmitted to the first node 231 of the latch 200.

When the fifth transistor 222 in the latch 200 is turned on, the ground voltage may be transmitted to the second node 232 of the latch 200.

In some examples, data that is actually latched by the latch may be judged through level information at the first node 231 of the latch 200. For example, when a level at the first node 231 of the latch 200 is a low level, the latch 200 latches the data “0”; and when a level at the first node 231 of the latch 200 is a high level, the latch 200 latches the data “1”.

In some examples, as shown in FIG. 4, the common data transmission circuit 400 comprises: a sixth transistor 411 and a seventh transistor 412 that are connected in series; a first end of the sixth transistor 411 is coupled to the sense node SO, a second end of the sixth transistor 411 is coupled to a first end of the seventh transistor 412, and a second end of the seventh transistor 412 is coupled to the ground terminal, wherein a control end of the seventh transistor 412 is coupled with the second port 402 of the common data transmission circuit 400, and a control end of the sixth transistor 411 is configured to receive a common data transmission signal Rdcom.

In some examples, the sixth transistor 411 may also be replaced with a thyristor and a switching element.

The control logic circuit in FIG. 5 may be further configured to generate the common data transmission signal Rdcom.

With respect to the page buffer in FIG. 2, since the page buffer has a plurality of independent data transmission circuits, and each independent data transmission circuit has its corresponding independent data transmission signal Rd (e.g., Rd_s, Rd_L, Rd_1, Rd_2 and Rd_c), if the number of the latches is m (m is a positive integer greater than or equal to 2), the above-mentioned control logic circuit 500 needs to generate m different independent data transmission signals Rd. In one of the examples of the present disclosure, as shown in FIG. 4, 6 latches of the page buffer share one common data transmission circuit 400, and thus only 1 common data transmission signal Rdcom needs to be generated. This greatly simplifies an internal circuit design of the control logic circuit 500, which can further reduce the area of the control logic circuit, thereby reducing the area of the memory.

Therefore, the solution of the examples of the present disclosure can not only reduce the area of the page buffer 100, but also correspondingly reduce the area of the control logic circuit 500, which further reduces the area of the memory, and is favorable to achievement of a high integration level and a small size of the memory.

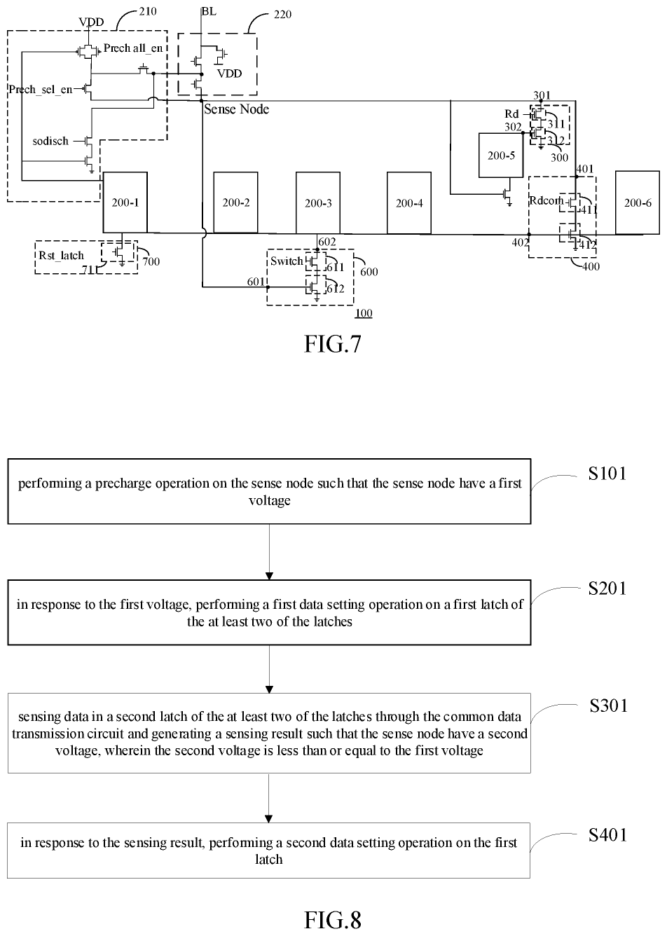

In some examples, as shown in FIG. 7, the page buffer further comprises: independent data transmission circuit 300, wherein a latch 200 that is not coupled with the common data transmission circuit 400 corresponds to one independent data transmission circuit 300.

It may be understood that when the number of the latches in the page buffer 100 is fixed, if all the latches 200 share one common data transmission circuit 400, the saved area is maximum, in other words, the occupied area is minimum.

However, it should be understood that as long as there are at least two of the latches 200 in the page buffer 100 that share one common data transmission circuit 400, it is sufficient to achieve the effect of saving the area of the page buffer 100.

As shown in FIG. 7, a latch 200 in the page buffer 100 which is not coupled with the common data transmission circuit 400 corresponds to one independent data transmission circuit 300. First port 301 of the independent data transmission circuit is connected with the sense node SO, and the second port 302 of the independent data transmission circuit is connected with the latches (e.g., the latch 200-5).

In some examples, the independent data transmission circuit 300 comprise: eighth transistor 311 and ninth transistor 312 that are connected in series; a first end of the eighth transistor 311 is coupled to the sense node SO, a second end of the eighth transistor 311 is coupled to a first end of the ninth transistor 312, and a second end of the ninth transistor 312 is coupled to the ground terminal, wherein a control end of the ninth transistor 312 is coupled to an output end of the corresponding latch 200 (for example, as shown in FIG. 6, it may be the first node 231 of the latch 200), and a control end of the eighth transistor 311 is configured to receive an independent data transmission signal Rd.

The eighth transistor 311 and the ninth transistor 312 include, but are not limited to, P-type transistors or N-type transistors. In the examples of the present disclosure, the illustration is made by taking the eighth transistors 311 and the ninth transistors 312 being the N-type transistors as an example.

The independent data transmission circuit 300 is configured to sense data latched in the latch 200 that is connected with the independent data transmission circuit 300. When the independent data transmission signal Rd is enabled, the data latched in the latch 200 may be sensed according to whether a high level at the sense node SO is discharged to a low level. For example, if the high level at the sense node SO is discharged to the low level, the data latched in the latch 200 is “1”; and if the sense node SO maintains the high level, the data latched in the latch is “0”.

In some examples, if the page buffer 100 comprises the independent data transmission circuit 300 and the common data transmission circuit 400, data transmission may be performed on any two of the latches 200 in the page buffer 100 using the independent data transmission circuit 300 and the common data transmission circuit 400.

In some examples, as shown in FIG. 4, the plurality of latches include: a sense latch 200-1; the precharge and discharge circuit 210 comprises: a tenth transistor 211, wherein a first end of the tenth transistor 211 is coupled to the power terminal, a second end of the tenth transistor 211 is coupled to the sense node SO, a control end of the tenth transistor 211 is coupled to the sense latch 200-1, and the tenth transistor 211 is configured to provide the first voltage to at least one of the bit line voltage setting circuit 220 or the sense node according to the data latched in the sense latch 200-1.

The tenth transistor 211 may be directly or indirectly coupled to the sense node SO, for example, the tenth transistor 211 may be also connected with an eleventh transistor 212, and coupled with the sense node SO through the eleventh transistor 212. The eleventh transistor 212 is configured to receive the Prech_sel_en signal.

For example, when the data latched in the sense latch 200-1 is “1”, and the tenth transistor 211 is a P-type transistor, the control end of the tenth transistor 211 is configured to receive an inversion signal of the latched data “1”, i.e., to receive data “0”, such that the tenth transistor 211 is turned on, and when the Prech_sel_en signal is enabled, a voltage at the sense node SO is set as a high voltage. The first voltage is a voltage provided by the power terminal, such as VDD.

As shown in FIG. 4, the precharge and discharge circuit 210 further comprises a twelfth transistor 213. If the twelfth transistor 213 is an N-type transistor, when the data latched in the sense latch 200-1 is “0”, the twelfth transistor 213 is turned on, and the ground voltage is provided to the sense node SO.

The precharge and discharge circuit 210 further comprises a thirteenth transistor 214, wherein a first end of the thirteenth transistor 214 is coupled to the power terminal, a second end of the thirteenth transistor 214 is coupled to the sense node SO, the thirteenth transistor 214 is configured to receive the Prech_all_en signal, and when the thirteenth transistor 214 is turned on, the first voltage is provided to at least one of the bit line voltage setting circuit 220 or the sense node SO.

In some examples, when the thirteenth transistor 214 and the eleventh transistor 212 are turned on, the first voltage is provided to the sense node SO based on the power supply voltage VDD provided from the power terminal.

In some examples, as shown in FIG. 4, the plurality of latches include: the sense latch 200-1 and a cache latch 200-6, wherein the sense latch 200-1 and the cache latch 200-6 are coupled with the second port 402 of the common data transmission circuit 400 respectively.

The sense latch 200-1 may be configured to store inhibition information and verification information from a verify operation.

The cache latch 200-6 is configured to perform data exchange with the outside, for example, external data is first transmitted to the cache latch 200-6, and then transmitted to the sense latch 200-1 through the cache latch 200-6. For another example, the data in the sense latch 200-1 is transmitted to the cache latch 200-6, and then transmitted to the outside through the cache latch 200-6. The outside may be the memory controller or the host, etc.

In some examples, as shown in FIG. 4, the plurality of latches further include: data latches (e.g., a D1 latch 200-3, a D2 latch 200-4 and a Dm latch 200-5) and/or a low voltage latch 200-2, wherein the sense latch 200-1, the cache latch 200-6, the data latches (200-3, 200-4 and 200-5) and/or the low voltage latch 200-2 are coupled with the second port 402 of the common data transmission circuit 400 respectively.

If the memory cell is an SLC, the latches in the page buffer 100 may include the cache latch 200-6, wherein the cache latch 200-6 may be configured to latch data of the memory cell.

If the memory cell is an MLC, in addition to the cache latch 200-6, the page buffer 100 may further comprise one data latch, e.g., the D1 latch 200-3. The D1 latch 200-3 may be configured to latch data of a lower page of the memory cell, and the cache latch 200-6 may be configured to latch data of a upper page of the memory cell.

If the memory cell is a TLC, in addition to the cache latch 200-6, the page buffer 100 may further comprise two data latches, e.g., the D1 latch 200-3 and the D2 latch 200-4. The D1 latch 200-3 may be configured to latch the data of the lower page of the memory cell, the D2 latch 200-4 may be configured to latch data of a middle page of the memory cell, and the cache latch 200-6 may be configured to latch the data of the upper page of the memory cell.

By analogy, if the memory cell is an nLC, the number of the data latches in the page buffer may be n−1, wherein the n−1 data latches respectively latch the data of designated pages of the memory cell, and n is a positive integer greater than 0.

In some examples, the cache latch may also be used for other functions, for example, for temporarily storing verification information. At this time, if the memory cell is the nLC, the number of the data latches in the page buffer may be n, and n is a positive integer greater than 0.

The low voltage latch 200-2 may be configured to store the inhibition information and adjusted verification information from a verify operation.

In some examples, the low voltage latch 200-2 may be also connected with another precharge and discharge circuit (not shown in FIG. 4), so as to set the voltage of the bit line based on the precharge and discharge circuit by using the inhibition information and the adjusted verification information from the verify operation that are stored by the low voltage latch 200-2.

On the one hand, compared with the page buffer 100 as shown in FIG. 2, the plurality of latches 200 in the page buffer 100 provided by the examples of the present disclosure share the common data transmission circuit 400, then the area of the page buffer 100 can be saved by 6-7%; moreover, since the peripheral circuit of the memory comprises a plurality of the page buffers 100, the area of the peripheral circuit can be greatly reduced, which is favorable to the further reduction of the size of the memory.

On the other hand, compared with the page buffer 100 as shown in FIG. 2, since the data transmission circuits in the page buffer 100 provided by the examples of the present disclosure are fewer, under the condition that the area occupied by the page buffer 100 is unchanged, more latches may be disposed (e.g., the Dm latch is added), so as to meet demands of the memory of higher bit data, such that more bits of data information may be stored, which is favorable to the increase of a bit density of the memory.

Based on the above-mentioned memory, examples of the present disclosure further provide an operation method of a memory.

FIG. 8 is a flow diagram of an operation method of a memory provided by examples of the present disclosure. The memory comprises a memory cell array and a page buffer, wherein the page buffer is disposed correspondingly to a bit line of the memory cell array and comprises a plurality of latches and at least one common data transmission circuit; a first port of the common data transmission circuit is coupled with a sense node, and a second port of the common data transmission circuit is coupled with at least two of the latches. As shown in FIG. 8, the operation method at least comprises the following operations: operation S101, performing a precharge operation on the sense node such that the sense node have a first voltage; operation S201, in response to the first voltage, performing a first data setting operation on a first latch of the at least two of the latches; operation S301, sensing data in a second latch of the at least two of the latches through the common data transmission circuit and generating a sensing result such that the sense node have a second voltage, wherein the second voltage is less than or equal to the first voltage; and operation S401, in response to the sensing result, performing a second data setting operation on the first latch.

It is to be noted that the above-mentioned first latch is a latch of the plurality of latches to which data is written, and the second latch is a latch of the plurality of latches that actively transmits the data.

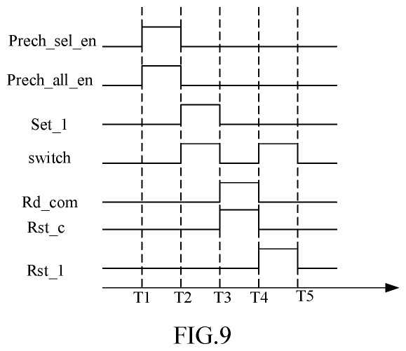

In conjunction with the timing diagram in FIG. 9 and the page buffer 100 in FIG. 4, the above operations are illustrated below in detail by taking transmitting data in the cache latch 200-6 to the D1 latch 200-3 as an example. It can be understood that, in this example, the cache latch 200-6 is the second latch, and the D1 latch 200-3 is the first latch.

In operation S101, the precharge operation is performed on the sense node such that the sense node have the first voltage.

Within time T1 to T2, a thirteenth transistor 214 in a precharge and discharge circuit 210 is turned on in response to an enabled signal Prech_all_en, and an eleventh transistor 212 is turned on in response to an enabled signal Prech_sel_en, so as to perform the precharge operation on the sense node SO that that the sense node SO have the first voltage that may be a power supply voltage VDD from a power terminal. Here, the enabled signal Prech_all_en is a signal that is applied to a control end of the thirteenth transistor 214, and the enabled signal Prech_sel_en is a signal that is applied to a control end of the eleventh transistor 212.

In operation S201, in response to the first voltage, the first data setting operation is performed on the first latch of the at least two of the latches.

Within time T2 to T3, in response to a high voltage (e.g., VDD) from the sense node SO, the first data setting operation is performed on the D1 latch 200-3. For example, the D1 latch 200-3 is set as “1”.

In some examples, as shown in FIG. 4, the page buffer 100 further comprises a first data setting circuit 600, wherein the first port 601 of the first data setting circuit 600 is coupled with the sense node SO, and a second port 602 of the first data setting circuit 600 is coupled with the at least two of the latches 200. The second port 402 of the common data transmission circuit 400 is coupled to a coupling node between the second port 602 of the first data setting circuit 600 and the at least two of the latches 200. The operation S201 above comprises: in response to the first voltage and a first data setting signal, providing, by the first data setting circuit, a ground voltage from a ground terminal to the first latch, and latching, by the first latch, initial data information based on the ground voltage.

In an example, setting the D1 latch 200-3 as “1” comprises: within the period from T2 to T3, a first transistor 611 in the first data setting circuit 600 is turned on in response to an enabled signal Switch, and a second transistor 612 is turned on in response to a high voltage from the sense node SO; therefore, the ground voltage VSS from the ground terminal is transmitted to the second port 602 of the first data setting circuit 600 (i.e., the third node 233 of the latch 200 in FIG. 6) through the second transistor 612 and the first transistor 611. Here, the enabled signal Switch is the first data setting signal that is applied to a control end of the first transistor 611.

A fifth transistor 222 in the D1 latch 200-3 is turned on in response to a corresponding set signal Set1, such that the ground voltage VSS at the third node 233 of the latch 200 is transmitted to a second node 232, and the first node 231 of the latch 200 latches a high voltage, that is, the D1 latch 200-3 is set as data “1”.

In operations S301 and S401, the data in the second latch of the at least two of the latches is sensed by the common data transmission circuit, and the sensing result is generated such that the sense node have the second voltage, wherein the second voltage is less than or equal to the first voltage; and in response to the sensing result, the second data setting operation is performed on the first latch.

In some examples, the second latch latches target data information. The second latch latches data information to be transmitted to the first latch, which may be referred to as the target data information.

The operation S301 above comprises: applying a common data transmission signal to the common data transmission circuit, sensing the target data information through the common data transmission circuit, and generating the sensing result such that the sense node have the second voltage.

The operation S401 above comprises: in response to the second voltage and the first data setting signal, performing the second data setting operation on the first latch.

In some examples, when the target data information corresponds to a high level, the second voltage is less than the first voltage; and when the target data information corresponds to a low level, the second voltage is equal to the first voltage.

Within the period from T3 to T4, the target data information in the cache latch 200-6 may be sensed using the common data transmission circuit 400. In conjunction with FIGS. 6 and 4, if the target data information is “1”, within the period from T3 to T4, the cache latch 200-6 turns on a fourth transistor 221 in FIG. 6 in response to a corresponding reset signal Rst_c, so as to transmit the target data information to the second port 402 of the common data transmission circuit 400, and turns on a seventh transistor 412 in the common data transmission circuit 400 based on the target data information “1”. Meanwhile, within the period from T3 to T4, a control end of a sixth transistor 411 in the common data transmission circuit 400 is configured to be turned on when receiving an enabled signal Rdcom. Under the condition that the sixth transistor 411 and the seventh transistor 412 are both turned on, the high level at the sense node SO may be discharged through the common data transmission circuit 400, so as to obtain the second voltage at a low level after discharging. It can be understood that the second voltage is less than the first voltage at this time. The second voltage may be configured to embody the sensing result. It may be inferred through the sensing result that the target data information latched in the cache latch 200-6 is “1”. Here, the enabled signal Rdcom is a common data transmission signal that is applied to the control end of the sixth transistor 411.

If the target data information is “0”, within the period from T3 to T4, the cache latch 200-6 turns on the fourth transistor 221 in response to a corresponding reset signal Rst_c, so as to transmit the target data information to the second port 402 of the common data transmission circuit 400, and turns off the seventh transistor 412 in the common data transmission circuit 400 based on the target data information “0”. Meanwhile, within the period from T3 to T4, the control end of the sixth transistor 411 in the common data transmission circuit 400 is configured to be turned on when receiving the enabled signal Rdcom. Under the condition that the sixth transistor 411 is turned on but the seventh transistor 412 is turned off, the sense node SO maintains a high level, and the voltage of the sense node SO is the second voltage at this time. It can be understood that the second voltage is equal to the first voltage at this time. The second voltage is configured to embody the sensing result. The sensing result indicates that the target data information latched in the cache latch 200-6 is “0”.

Within the period from T4 to T5, operation S401 is performed by performing the second data setting operation on the first latch in response to the sensing result.

In an example, if the sensing result indicates that the target data information latched in the cache latch 200-6 is “1”, at this time, the sense node SO has the second voltage which is less than the first voltage, and the first data setting circuit 600 cannot be turned on in response to the second voltage at this time; therefore, the data in the D1 latch 200-3 still keeps the initial data information “1” latched after the first data setting operation. That is, it may be regarded as that the cache latch 200-6 transmits the data “1” to the D1 latch 200-3.

If the sensing result indicates that the target data information latched in the cache latch 200-6 is “0”, at this time, the sense node SO has the second voltage which is equal to the first voltage, the first data setting circuit 600 may be turned on in response to the voltage on the sense node SO, and the fourth transistor 221 in the D1 latch 200-3 is turned on in response to a corresponding reset signal Rst_1, such that the initial data information “1” latched in the D1 latch 200-3 may be discharged to the second data “0” through the first data setting circuit. That is, it may be regarded as that the cache latch 200-6 transmits the data “0” to the D1 latch 200-3.

The examples of the present disclosure achieve functions of performing sensing on the different latches 200 and performing data transmission between two of the latches 200 by reusing the common data transmission circuit 400.

Examples of the present disclosure further provide a memory system. As shown in FIG. 1A, the memory system 30 comprises: one or more memories 34 of any one of the above examples; and a memory controller 32 coupled to the memories 34 and configured to control the memories 34.

Examples of the present disclosure further provide an electronic device. As shown in FIG. 1A, the electronic device comprises the memory system 30 as described in the above examples.

It is to be understood that, references to “one example” or “an example” throughout this specification mean that particular features, structures, or characteristics related to the example are included in at least one example of the present disclosure. Therefore, “in one example” or “in an example” presented everywhere throughout this specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent advantages or disadvantages of the examples.

It is to be noted that, the terms “comprise”, “include” or any variants thereof herein are intended to cover non-exclusive inclusion, such that a process, a method, an article or a device comprising a series of elements comprise not only those elements, but also other elements not listed explicitly, or elements inherent to this process, method, article or device. An element defined by a statement “comprising one” do not preclude the presence of another identical element in the process, method, article or device comprising this element, without more limitations.

The above descriptions are merely implementations of the present disclosure, and the protection scope of the present disclosure is not limited to these. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory, comprising:
a memory cell array; and
a page buffer, wherein the page buffer is disposed correspondingly to a bit line of the memory cell array and comprises:
latches which are coupled to the bit line through a sense node of the page buffer; and
at least one common data transmission circuit, wherein a first port of the common data transmission circuit is coupled to the sense node, and wherein a second port of the common data transmission circuit is coupled to at least two of the latches that are configured for data sensing through the common data transmission circuit.

2. The memory of claim 1, wherein data transmission is performed between the at least two of the latches through the common data transmission circuit.

3. The memory of claim 1, wherein the page buffer comprises a first data setting circuit, wherein a first port of the first data setting circuit is coupled to the sense node and a second port of the first data setting circuit is coupled to the at least two of the latches, wherein
the first data setting circuit is configured to set data latched in the latches; and
the second port of the common data transmission circuit is coupled to a coupling node between the second port of the first data setting circuit and the at least two of the latches.

4. The memory of claim 3, wherein the first data setting circuit comprises a first transistor and a second transistor that are connected in series, wherein
a first end of the first transistor is coupled to the second port of the first data setting circuit;
a second end of the first transistor is coupled to a first end of the second transistor; and
a second end of the second transistor is coupled to a ground terminal, wherein a control end of the second transistor is coupled to the sense node, and a control end of the first transistor is configured to receive a first data setting signal.

5. The memory of claim 4, wherein the page buffer further comprises a second data setting circuit comprising a third transistor, wherein
a first end of the third transistor is coupled to the second port of the common data transmission circuit;
a second end of the third transistor is coupled to a ground terminal; and
a control end of the third transistor is configured to receive a second data setting signal.

6. The memory of claim 4, further comprising a control logic circuit coupled to the first data setting circuit and the second data setting circuit, wherein the control logic circuit is configured to generate at least one of the first data setting signal or the second data setting signal.

7. The memory of claim 1, wherein the latches comprise:
first phase inverters;
second phase inverters;
fourth transistors; and
fifth transistors, wherein
output ends of the first phase inverters are coupled to input ends of the second phase inverters;
input ends of the first phase inverters are coupled to output ends of the second phase inverters;
first ends of the fourth transistors are coupled to first nodes between the output ends of the first phase inverters and the input ends of the second phase inverters;
first ends of the fifth transistors are coupled to second nodes between the input ends of the first phase inverters and the output ends of the second phase inverters; and
second ends of the fourth transistors and second ends of the fifth transistors are coupled to third nodes, wherein the third nodes of at least two of the latches are coupled to the second port of the common data transmission circuit.

8. The memory of claim 1, wherein the common data transmission circuit comprises a sixth transistor and a seventh transistor that are connected in series, wherein
a first end of the sixth transistor is coupled to the sense node;
a second end of the sixth transistor is coupled to a first end of the seventh transistor; and
a second end of the seventh transistor is coupled to a ground terminal, wherein a control end of the seventh transistor is coupled to the second port of the common data transmission circuit, and a control end of the sixth transistor is configured to receive a common data transmission signal.

9. The memory of claim 1, wherein the page buffer further comprises independent data transmission circuits, wherein a latch that is not coupled with the common data transmission circuit corresponds to one of the independent data transmission circuits.

10. The memory of claim 9, wherein one of the independent data transmission circuits comprises an eighth transistor and a ninth transistor that are connected in series, wherein
a first end of the eighth transistor is coupled to the sense node;
a second end of the eighth transistor is coupled to a first end of the ninth transistor; and
a second end of the ninth transistor is coupled to a ground terminal, wherein a control end of the ninth transistor is coupled to an output end of the corresponding latch, and a control end of the eighth transistor is configured to receive an independent data transmission signal.

11. The memory of claim 1, wherein the page buffer further comprises:
a precharge and discharge circuit is coupled to a power terminal and the sense node; and
a bit line voltage setting circuit is coupled to: the precharge and discharge circuit, the sense node, and the bit line, wherein
the precharge and discharge circuit is configured to provide a first voltage from the power terminal to at least one of the bit line voltage setting circuit or the sense node; and
the bit line voltage setting circuit is configured to provide a bit line force voltage to the bit line based on the first voltage provided by the precharge and discharge circuit.

12. The memory of claim 11, wherein the latches include a sense latch, wherein the precharge and discharge circuit comprises:
a tenth transistor, wherein a first end of the tenth transistor is coupled to the power terminal;
a second end of the tenth transistor is coupled to the sense node;
a control end of the tenth transistor is coupled to the sense latch; and
the tenth transistor is configured to provide the first voltage to at least one of the bit line voltage setting circuit or the sense node according to data latched in the sense latch.

13. The memory of claim 1, wherein the latches include a sense latch and a cache latch, wherein the sense latch and the cache latch are coupled to the second port of the common data transmission circuit.

14. The memory of claim 13, wherein the latches further include at least one of a data latch or a low voltage latch, wherein at least one of the sense latch, the cache latch, the data latch, or the low voltage latch is coupled to the second port of the common data transmission circuit.

15. An operation method of a memory, wherein the memory comprises:
a memory cell array; and
a page buffer disposed correspondingly to a bit line of the memory cell array, wherein the page buffer comprises latches and at least one common data transmission circuit, wherein a first port of the common data transmission circuit is coupled to a sense node and a second port of the common data transmission circuit is coupled to at least two of the latches, wherein
the operation method comprising:
performing a precharge operation on the sense node such that the sense node has a first voltage;
in response to the sense node having the first voltage, performing a first data setting operation on a first latch of at least two of the latches;
sensing data in a second latch of the at least two of the latches through the common data transmission circuit;
generating a sensing result such that the sense node has a second voltage less than or equal to the first voltage; and
in response to the sense node having the second voltage, performing a second data setting operation on the first latch.

16. The operation method of claim 15, wherein the page buffer comprises a first data setting circuit, wherein
a first port of the first data setting circuit is coupled to the sense node;
a second port of the first data setting circuit is coupled to at least two of the latches;
a second port of the common data transmission circuit is coupled to a coupling node between the second port of the first data setting circuit and at least two of the latches; and wherein
performing the first data setting operation on the first latch of the at least two of the latches comprises:
in response to a first data setting signal, providing, by the first data setting circuit, a ground voltage from a ground terminal to the first latch; and
latching, by the first latch, initial data information based on the ground voltage.

17. The operation method of claim 16, wherein the second latch latches target data information, and wherein the method further comprises:
applying a common data transmission signal to the common data transmission circuit before sensing the data in the second latch of the at least two of the latches; and
in response to the sense node having the second voltage and the first data setting signal, performing the second data setting operation on the first latch.

18. The operation method of claim 17, wherein:
when the target data information corresponds to a high level, the second voltage is less than the first voltage; and
when the target data information corresponds to a low level, the second voltage is equal to the first voltage.

19. A memory system, comprising:
one or more memories; and
a memory controller coupled to the one or more memories and configured to control the one or more memories, wherein one of the one or more memories comprises:
a memory cell array; and
a page buffer, wherein the page buffer is disposed correspondingly to a bit line of the memory cell array and comprises:
latches coupled to the bit line through a sense node of the page buffer; and
at least one common data transmission circuit, wherein a first port of the common data transmission circuit is coupled to the sense node, and wherein a second port of the common data transmission circuit is coupled to at least two of the latches that are configured for data sensing through the common data transmission circuit.

20. The memory system of claim 19, wherein data transmission is performed between the at least two of the latches through the common data transmission circuit.
